(19) United States
(12) Patent Application Publication
(10) Pub. No.: US 2011/0018556 A1
(43) Pub. Date: Jan. 27, 2011

(54) PRESSURE AND TOUCH SENSORS ON FLEXIBLE SUBSTRATES FOR TOYS

(75) Inventors: KHANH M. LE, Morgan Hill, CA (US); DAVID M. HOLMES, Cupertino, CA (US); PAUL P. CAMPBELL, San Jose, CA (US); LING KUN L. CHENG, Sunnyvale, CA (US)

Correspondence Address: Thomas E. Schatzel;Law Offices of Thomas E. Schatzel, P.C., 200 Altura Vista, Los Gatos, CA, 95032, US

(73) Assignee: BOREI CORPORATION

(21) Appl. No.: 12/506,869

(22) Filed: Jul. 21, 2009

(51) Int. Cl. G01R 27/26

(52) U.S. Cl. 324/654; 324/658

(57) ABSTRACT

A capacitive sensor comprises patterned electrodes and printed wires of conductive material integrated with sensing circuits on flexible circuit substrates. The flexible circuit substrates are fingered or otherwise elongated to distribute sensing points to the limbs in a toy doll or animal, or squares on a board game. Such sensing points can detect the presence of a finger even though actual contact is not made by measuring the proportions and changes in stray capacitance attaching to the various electrodes. Touch sensors are therefore possible even when the capacitor sensor's sensing points are covered by a doll's plastic skin or a plush animal's fur. Including an interlayer of open cell foam under the flexible circuit substrate further implements a pressure sensor because applied pressures will deform the geometries of the capacitor electrodes and dielectrics enough to produce a measurable change in capacitance.

### BACKGROUND OF THE INVENTION

1. Field of the Invention

The present invention relates to electronic sensors, and in particular to pressure and touch sensors implemented directly on flexible substrates and based on measurements of capacitance variances.

2. Description of the Prior Art

Toys can be far more interesting to play with if they are able to interact with children and adults. One key to enabling interaction is to equip a toy with sensors that can detect when and how the toy is being touched. A touch on the toys hand, if a doll, can be interpreted differently than pressure applied to the foot. A touch on the head of a toy dog could be sensed and interpreted as a pat, and an appropriate response of the toy dog would be to wag its tail.

Such pressure sensors need not be the precision instruments nor highly calibrated as commonly used in process control and scientific instrumentation. Very often, a touch having a pressure sense of a few ounces or more is enough to trigger and on-off output for a toy sensor. Temperature may also be interesting, as in having a toy comment verbally if the room environment is above, at, or below room temperature.

Mass produced products like toys are highly sensitive to component costs. So a practical touch sensor for a toy would need to be very inexpensive to manufacture.

### SUMMARY OF THE INVENTION

Briefly, a capacitive sensor embodiment of the present invention comprises patterned electrodes and printed wires of conductive material integrated with sensing circuits on flexible circuit substrates. The flexible circuit substrates are fingered or otherwise elongated to distribute sensing points to the limbs in a toy doll or animal, or squares on a board game. Such sensing points can detect the presence of a finger even though actual contact is not made by measuring the proportions and changes in stray capacitance attaching to the various electrodes. Touch sensors are therefore possible even when the capacitor sensor's sensing points are covered by a doll's plastic skin or a plush animal's fur. Including an interlayer of open cell foam under the flexible circuit substrate further implements a pressure sensor because applied pressures will deform the geometries of the capacitor electrodes and dielectrics enough to produce a measurable change in capacitance.

These and other objects and advantages of the present invention will no doubt become obvious to those of ordinary skill in the art after having read the following detailed description of the preferred embodiments that are illustrated in the various drawing figures.

### IN THE DRAWINGS

FIG. 1 is a functional block diagram and schematic of a toy automation device embodiment of the present invention;

FIGS. 2A and 2B are a perspective diagram and a schematic diagram of a capacitive proximity sensor embodiment of the present invention showing how the relative position of a finger presents different stray capacitances;

FIG. 3 is a perspective and schematic diagram of a board game embodiment of the present invention showing how the relative position of a game piece on the board can present different stray capacitances;

FIGS. 4A and 4B are cross sectional views of a capacitive pressure sensor embodiment of the present invention which has a soft flexible dielectric substrate with top and bottom conductor layers, and FIG. 4A shows the capacitive pressure sensor before pressure is applied from above, and FIG. 4B represents how the top and bottom conductor layers are pressed closer together when pressure is being applied;

FIGS. 5A and 5B are cross sectional views of a capacitive pressure sensor array embodiment of the present invention which has a soft flexible dielectric middle layer, with top and bottom conductor layers on single-sided flexible circuit substrates, and FIG. 5A shows the capacitive pressure sensor array before any pressure is applied, and FIG. 5B represents how the capacitive pressure sensors nearer the center are pressed closer together more than at the edges when a point pressure is applied at the center from above;

FIG. 6 is a perspective view diagram of an L-C pressure sensor embodiment of the present invention built with both inductors and capacitors on a foam substrate that will compress and flex under pressure;

FIGS. 7A and 7B are schematics of how a circuit on the sensor of FIG. 6 could be wired to operate, and how a pressure being applied would deform the tuned L-C components enough to cause a change in resonant frequency;

FIG. 8 is a plan view diagram of a flex circuit that was used in a prototype of toy doll embodiment of the present invention; and

FIG. 9 is a perspective exploded assembly view diagram of a flex circuit and sensor electronics assembly mounted in a back torso of a toy doll, in an embodiment of the present invention.

### DETAILED DESCRIPTION OF THE PREFERRED EMBODIMENT

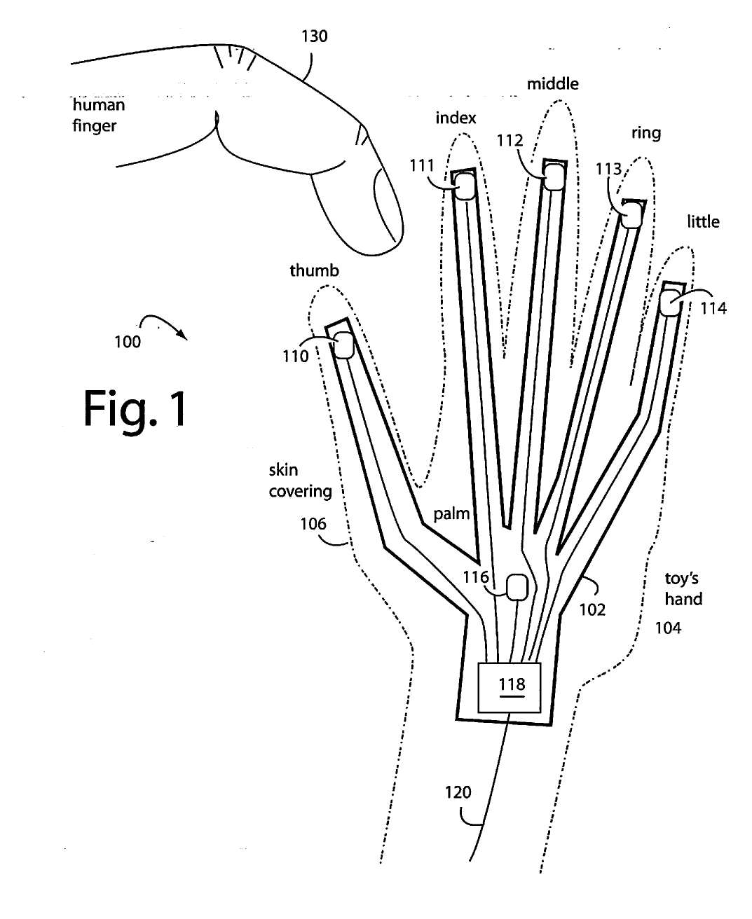

FIG. 1 represents a toy automation device embodiment of the present invention, and is referred to herein by the general reference numeral 100. Device 100 has a flexible circuit substrate 102 patterned to fit within a toy, in this case a hand 104 of the toy. A plastic skin covering 106 covers the toy's hand 104 and completely encloses device 100 within. In animal toys, skin 106 would consist of simulated animal fur or fish scales that are non-conductive to electricity.

Device 100 further includes capacitive proximity sensors 110-114 in the thumb, index, middle, ring, and little fingers, and another capacitive proximity sensor 116 in the palm. These are all mounted directly on, or fashioned from, printed, patterned circuits on the flexible circuit substrate 102. The capacitive proximity sensors are all connected by printed wires to a sensor controller 118, also disposed directly on the flexible circuit substrate 102. A connection 120 provides for communication and control signals, e.g., to other devices in the toy.

Two conductors separated by a dielectric material can be used to form a capacitor. The capacitance of that capacitor is a function of the dielectric constant of the dielectric layer, the areas of the conductors separated, and the separation distance. If any of these change, the capacitance changes accordingly. A mechanical arrangement in which pressure compresses the separation distance of the dielectric layer will cause an increase in capacitance proportional to the pressure.

In FIG. 1, capacitive proximity sensor 111 is shown that is sensitive to the near proximity and contact of a finger 130. As finger 130 approaches capacitive proximity sensor 111, a capacitive coupling develops, and controller 118 converts the change in capacitance to a digital value. In the simplest case, such value would be a one-bit binary, for touch/no-touch. In a more complex embodiment, the value could be a multi-bit binary and a measure of the distance to finger 130. Skin covering 106 is intervening, and so will prevent actual contact.

A flex substrate capacitor can be used that comprises a top, patterned layer, a flexible substrate, and a bottom plate. A capacitance is formed when the dielectric layer of flexible substrate separates the two conductor plates of patterned layer and bottom plate. If the area of the conductors, the thickness of the dielectric material separating the conductor, or the distance between the two conductors changes, the effective capacitance changes. The effective capacitance also increases significantly if stray capacitances, like a finger of a child or an adult couple-in, in parallel, or another conductor with an effectively large area contacts the top, patterned layer.

The material of flexible substrate 102 can be polyimide, polyester, a flame retardant fiberglass and resin type-FR4, or other industry standard flexible printed circuit board (PCB) substrate material.

A toy with device 100 can receive user input by touch and react according to the way it is touched, where on the toy it is touched, and when in a sequence of events it is touched. The toy can be programmed to respond in ways that depend on the nature of the touch sensed. The response can consist of a physical movement of the toy, speech or sound from the toy, light output from the toy from various LED's located on the toy, or a combination of responses.

The flexible substrate, sensors and other electronics like that shown in FIG. 1 require very little space. It can therefore be easily embedded into different parts of even preexisting toys. Choosing the patterns and materials used for the conductive materials on the flexible substrate allows for a great range of structures and topographies, each with a corresponding set of sensitivities and characteristics.

In general, it is preferable to keep wiring runs between capacitor pads and their sensing circuits as short as possible. This helps avoid the problems associated with trying to detect small changes of capacitance in the relatively large capacitance created by the wiring runs, and problems with other stray capacitances.

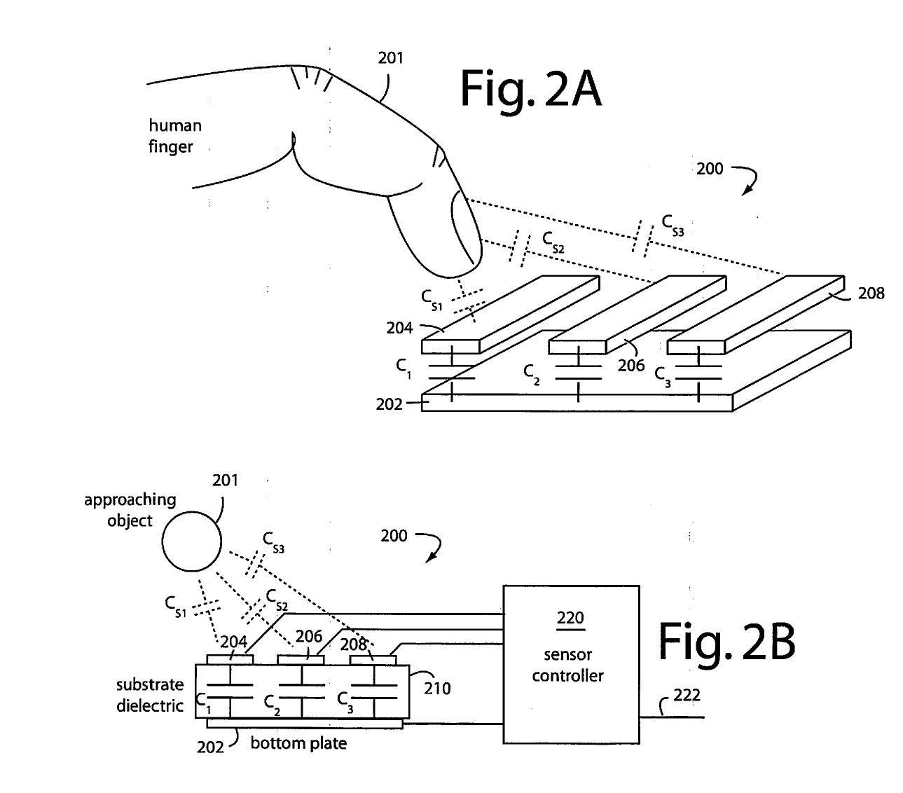

FIGS. 2A and 2B represent a capacitive proximity sensor 200 that would be useful in device 100 to detect the presence and relative position and movement of a finger 201. A bottom plate 202 and three top patterned electrodes 204, 206, and 208, are etched from copper on a flexible dielectric substrate 210 (not shown in FIG. 2A). A conventional way to do this would be to start with industry standard double-sided flexible printed circuits of polyimide or Mylar.

A sensor controller 220 (not shown in FIG. 2A) measures the capacitances (C₁, C₂, C₃) of the three top patterned electrodes 204, 206, and 208, and any stray capacitances, with respect to bottom plate 202. As finger 201 approaches, stray capacitances Cₛ₁, Cₛ₂, Cₛ₃, grow in significance and will vary amongst themselves dependant on which is the closest and which is the farthest from the finger or other approaching object 201. There is informational value in determining the position and velocity of finger 201 beyond just knowing it is present. So, sensor controller 220 makes relative measurements of Cₛ₁, Cₛ₂, Cₛ₃, over time, to estimate the presence, position, and velocity of finger 201. An output 222 connects to other sensors, controllers, and actuators that enable a toy to produce an appropriate response to the presence, position, and velocity of finger 201. Such responses include speech, listening, limb movement, eye opening, sneezing, memorizing, etc.

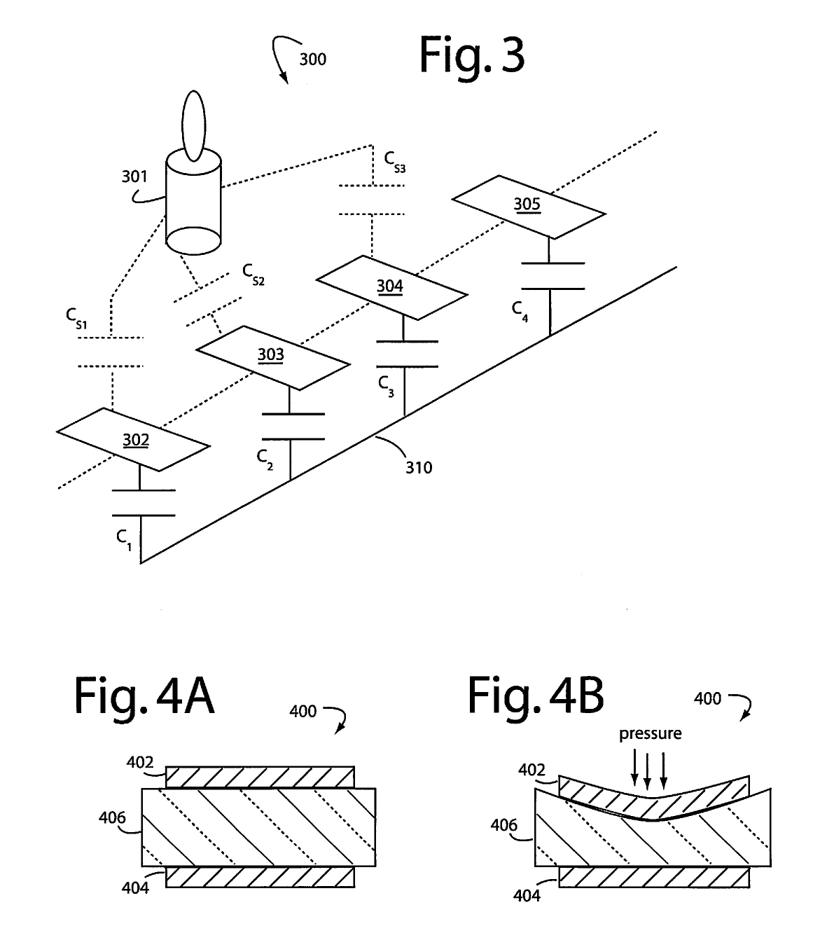

A board game 300 represented in FIG. 3 is similar in its instrumentation to capacitive proximity sensor 200. Here, a metallic game piece 301 is moved by the players along the surface of a board made of cardboard or plastic. Embedded within the game board are several electrodes 302-305 of copper etched or otherwise patterned on the topside of a flexible circuit substrate. A bottom electrode, or ground plane 310 is similarly fabricated on the bottom side of the flexible circuit substrate. A sensor controller, such as 220 in FIG. 2B, could be used to determine the movement, position, and identity of game piece 301 on the game board. Such would be useful for board games like MONOPOLY, CHUTES and LADDERS, 1862 CIVIL WAR, and puzzles, etc. A computer in wireless communication with the board game 300 could track player wins, losses, advances, and points scores. Game play could also be distributed in real-time around the world amongst several players.

FIGS. 4A and 4B represent a capacitive pressure sensor 400 based on a soft interlayer material and flexible substrate for use in toys, dolls, plush animals, puzzles, board games, etc. Capacitive pressure sensor 400 is constructed by separating two surface layers 402 and 404 of sheet copper or other conducting material with a flex substrate 406 of a porous dielectric material. For example, flexible open-cell foam and sponge material could be used. By pressing or squeezing the flex substrate, the distance between the conductive layers on the opposite surfaces decreases. Thus significantly increasing the capacitance of the capacitor formed. The increase can be proportional to the pressure applied up to the compression limit of the materials. A change in the distance between the two conducting layers causes a measureable change in the capacitance, and thus can be roughly interpreted as pressure with an accuracy sufficient for the needs of a toy or game play.

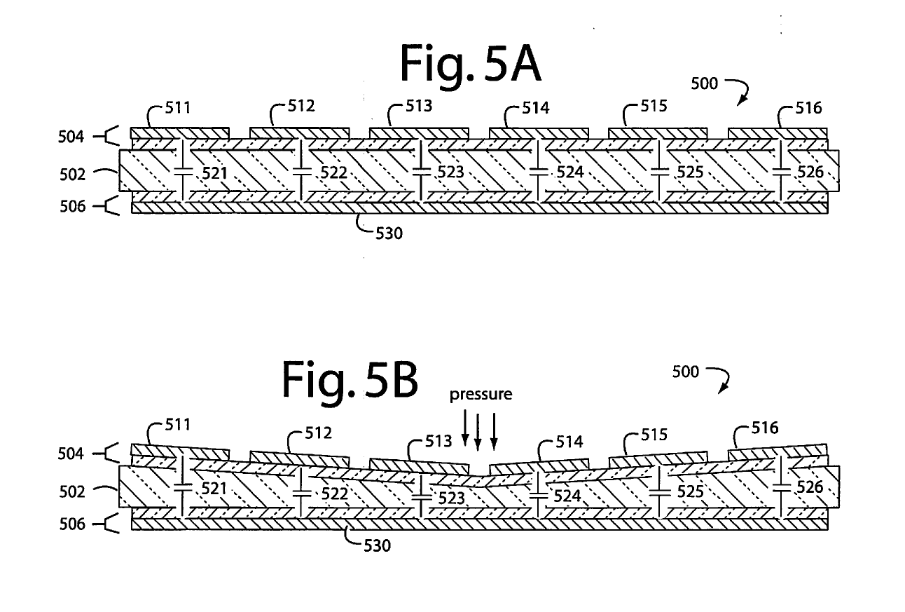

In another embodiment illustrated in FIGS. 5A and 5B, a capacitive pressure sensor array 500 comprises an open-cell foam dielectric layer 502 sandwiched between a top single-sided flex circuit 504 and a bottom single-sided flex circuit 506. The top single-sided flex circuit 504 can comprise several electrodes 511-516 that each form respective capacitors 521-526. The bottom single-sided flex circuit 506 is a conductive layer ground-plane 530 for all the capacitors, and can be more rigid and not as flexible as the top layers. FIG. 5B demonstrates what happens when a point of pressure is applied from above near the center of the surface field of electrodes 511-516. Capacitors 523 and 524 will increase in capacitance relative to capacitors 521 and 526 near the edges. The increase will be proportional to the applied pressure.

In an alternative embodiment that would reduce sensitivities to the proximity of a finger to a pressure sensor, as in FIGS. 2A and 2B, electrodes 511-516 could be buried inside the dielectric 502 between ground-planes 530 on opposite sides. That way, only pressure would have an effect on the capacitances of capacitors 521-526.

Determining the magnitude of bending and the location of the pressure points is possible with a device that measures the capacitances of each capacitor 521-526, e.g., sensor controller 220 in FIG. 2. Devices that can measure capacitances in the picoFarad, nanoFarad and microFarad ranges are conventional, and therefore need not be disclosed in detail here. The copper pattern of each of the several electrodes 511-516 can be tailored to match the application and particular conditions of use.

A flexible pressure sensor can be covered with cloth, fabrics, furs, plastic sheet, or other soft materials that can be either used in a toy at the surfaces or inside. When a flexible pressure sensor is embedded at a particular location in a toy, a change in pressure can be detected and interpreted according to its position from a measured change in capacitance. A pressure sensor with a flexible substrate can be embedded and extended into various parts of a toy with fingered elongations, as hinted at in FIG. 1. The pressure sensor output can be used as a trigger in a control system in another part of the toy or a nearby console.

Thick interlayers can reduce the sensitivity of a capacitor-only pressure sensor. In such cases, inductors can be included in the patterned top layer of the flexible circuit substrates to use inductance and capacitor changes in combination to sense pressures.

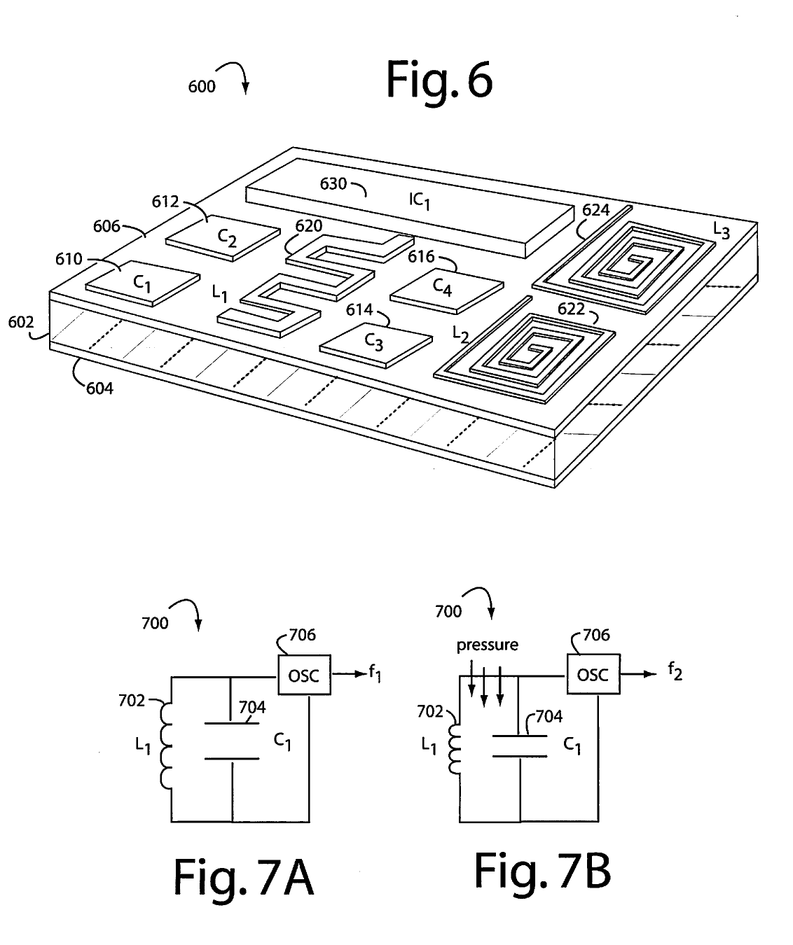

FIG. 6 shows a combination inductor-capacitor (L-C) pressure sensor embodiment of the present invention, and is referred to herein by the general reference numeral 600. Although L-C pressure sensor 600 is shown on a flat rectangular piece of foam substrate 602, when used in a toy it will probably be advantageous to shape the device with elongations that suit the particular spaces available and points needing instrumenting.

The foam substrate 602 has a conductive backing 604 and a top sheet 606 on which are disposed capacitor electrodes 610, 612, 614, and 616, and inductors 620, 622, and 624. An integrated circuit (IC) 630 is collocated with the capacitors and inductors formed to keep wiring runs short and manufacturing costs low.

FIGS. 7A and 7B suggest a partial circuit 700 that could be used for the L-C pressure sensor 600 of FIG. 6. One inductor 702 and one capacitor 704 are connected in a parallel L-C tank circuit that will resonate at a tune frequency of f₁ with the assistance of an oscillator-amplifier (OSC) 706. IC 630 of FIG. 6 could include several OSC 706 devices.

If the foam substrate 602 on which the inductors and capacitors are carried is subjected to a pressure from above, FIG. 7B represents that inductor 702 and capacitor 704 will be physically deformed or squashed. Such deformation will change the inductance and capacitance, and thus the resonant L-C will shift to f₂. The change in frequency output will be proportional to the pressure applied, and that can be used to trigger a response from a toy or game.

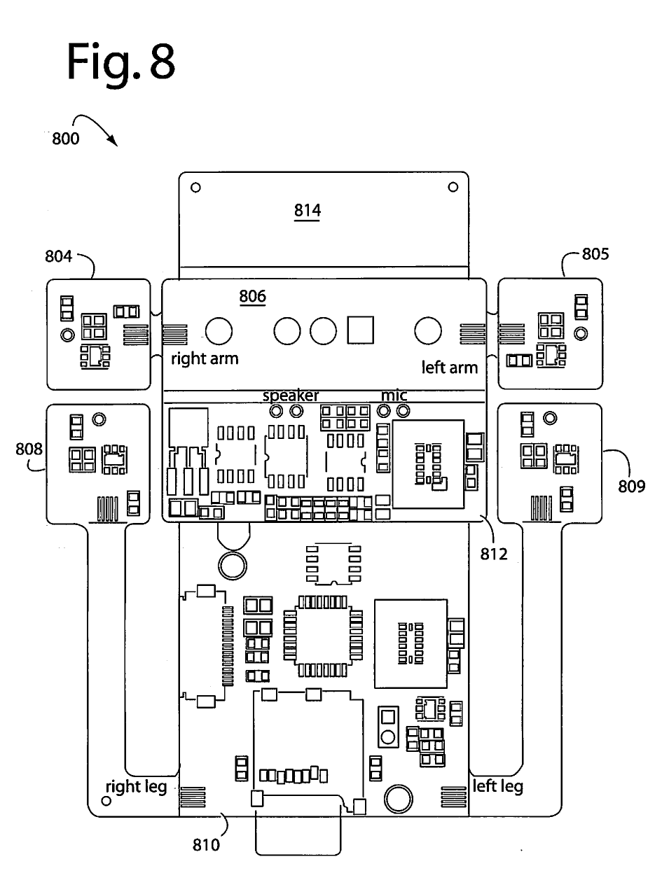

FIG. 8 represents a flex circuit 800 that was used in a prototype of toy doll embodiment of the present invention. Flex circuit 800 included right and left arm capacitive sensor circuits 804 and 805. These were elongations from circuit panel 806 which also provided for a power on/off switch (not shown). Right and left leg capacitive sensor circuits 808 and 809 were constructed as elongations of a main circuit panel 810. This attached to an audio circuit panel 812 having connections for a speaker and microphone. A panel 814 provided for mounting support and attachment inside the toy doll. A stiffer was included on the back, and a protective encapsulating coating was applied over the whole.

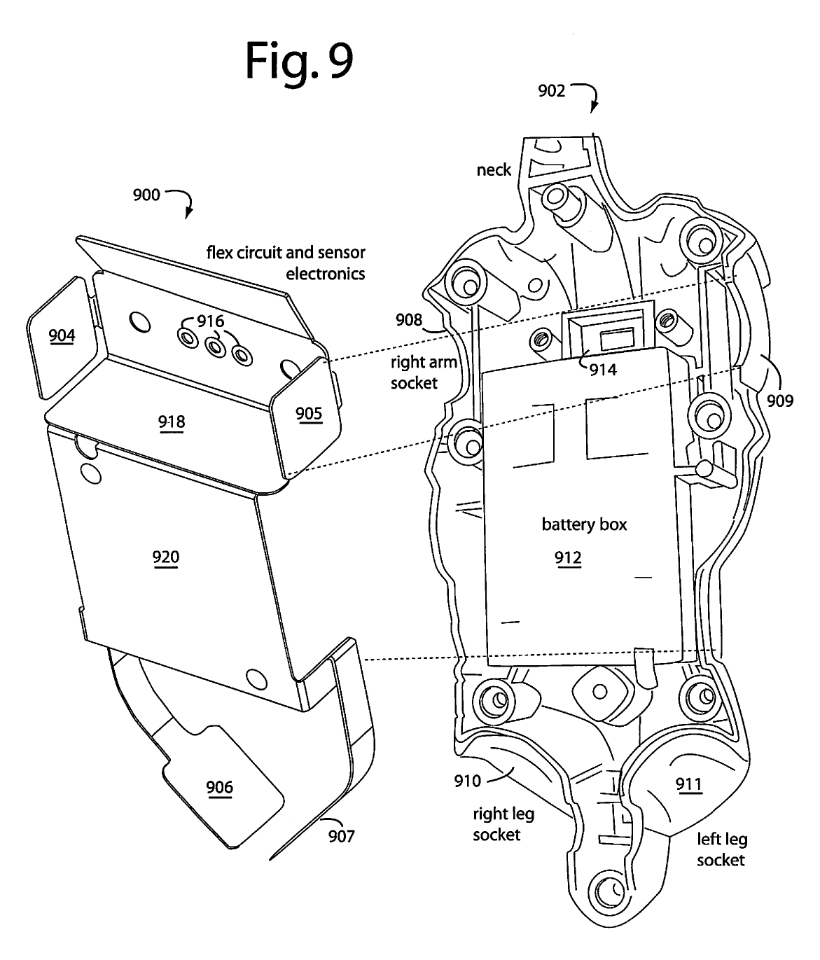

FIG. 9 shows how a flex circuit and sensor electronics assembly 900 can be mounted in the back torso 902 of a toy doll. A capacitive sensor and supporting touch sensor integrated circuit devices for the arms and legs are provided on elongation pads 904-907. These, in turn are fitted near arm and leg sockets 908-911. A battery box 912 provides operating power to flex circuit and sensor electronics assembly 900. An on/off switch (not shown) in switch pocket 914 connects to power switch pads 916. A microphone and speaker (not shown) can be connected to pads provided on a circuit panel 918. A main circuit panel 920 fits to the back of battery box 912, and provides for accelerometers, temperature sensors, touch sensor integrated circuit devices, and a microcontroller unit (MCU).

Although the present invention has been described in terms of the presently preferred embodiments, it is to be understood that the disclosure is not to be interpreted as limiting. Various alterations and modifications will no doubt become apparent to those skilled in the art after having read the above disclosure. Accordingly, it is intended that the appended claims be interpreted as covering all alterations and modifications as fall within the “true” spirit and scope of the invention.

1. A device to automate a toy, comprising:
a flexible substrate patterned to fit inside a toy;
a capacitive proximity sensor disposed in the flexible substrate and positioned inside said toy to detect a touch during play;
a control circuit connected to receive signals from the proximity sensor and also disposed in the flexible substrate, and for responding to said touch during play in a manner that is dependent on said position of the sensor inside said toy;
wherein, the proximity sensor is able to detect the near contact of a touch by a human through an intervening skin or covering of said toy.

2. The device of claim 1, further comprising:
a pressure sensor included in the proximity sensor that can provide a measure of the pressure applied by a touch.

3. The device of claim 1, further comprising:
another capacitive proximity sensor disposed in the flexible substrate and positioned at a different place inside said toy to detect another kind of touch during play;

4. A capacitive sensor, comprising:
a set of patterned electrodes and printed wires of conductive material integrated with sensing circuits on a flexible circuit substrate;
wherein, the flexible circuit substrate is fingered or otherwise elongated to distribute sensing points to the limbs in a toy doll or animal, or squares on a board game.

5. The capacitive sensor of claim 4, further comprising:
a plurality of sensing points that can detect the presence of a human finger even though actual contact is not made, by a device for measuring the proportions and changes in stray capacitance attaching to the various patterned electrodes;
wherein, a touch sensor is made possible even when capacitor sensing points are covered by a doll's plastic skin or a plush animal's fur.

6. The capacitive sensor of claim 4, further comprising:
an interlayer of open-cell foam under the flexible circuit substrate that implements a pressure sensor for applied pressures that deform the geometries of the patterned electrodes and dielectric separation distances enough to produce a measurable change in capacitance that is interpretable as a pressure.

7. The capacitive sensor of claim 6, further comprising:
an inductor disposed on the flexible circuit substrate that can be deformed in shape when a pressure from above is applied.

8. A pressure sensor, comprising:
a set of patterned electrodes and printed wires of conductive material integrated with sensing circuits on a flexible circuit substrate, wherein, the flexible circuit substrate is fingered or otherwise elongated to distribute sensing points to the limbs in a toy doll or animal, or squares on a board game;
an interlayer of open-cell foam under the flexible circuit substrate that implements a pressure sensor for applied pressures that deform the geometries of the patterned electrodes and dielectric separation distances enough to produce a measurable change in capacitance that is interpretable as a pressure; and
an inductor disposed on the flexible circuit substrate that can be deformed in shape when a pressure from above is applied.

9. The pressure sensor of claim 8, further comprising:
a tuned resonant circuit that combines the capacitances formed by the patterned electrodes and dielectric separation distances, with the inductor.

10. The pressure sensor of claim 9, further comprising:
an oscillator amplifier connected to the tuned resonant circuit that will output a frequency shift proportional to the degree of deformation to the interlayer of open-cell foam caused by an applied pressure from above.
